(19) United States
(12) Patent Application Publication
(10) Pub. No.: US 2023/0010514 A1
(43) Pub. Date: Jan. 12, 2023

(54) Method and Apparatus for Active Cooling of Electronics

(71) Applicant: Ventiva, Inc., San Jose, CA (US)

(72) Inventors: Rudy Vadillo, Gilroy, CA (US); Himanshu Pokharna, Saratoga, CA (US); Carl Schlachte, Ben Lomand, CA (US)

(73) Assignee: Ventiva, Inc., San Jose, CA (US)

(21) Appl. No.: 17/373,588

(22) Filed: Jul. 12, 2021

(51) Int. Cl. G06F 1/20; H05K 7/20; H05K 1/02; H05K 5/03

(52) U.S. Cl. CPC G06F 1/20; H05K 7/20136; H05K 1/0201; H05K 5/03; H05K 2201/064

(57) ABSTRACT

The present invention is directed to an electronic device with an ionic wind generator assembly that provides flow of air stream inside the housing of the device. The ionic wind generator assembly with a cover assembly and a catalyst provide a mechanism for cooling heated components embedded on a PCB of the electronic device. The cover assembly is configured depending on the orientation of the ionic wind generators to increase cooling when there is a narrow gap between the PCB and the ionic wind generator assembly through which the airstream flows for cooling of the internal components.

### CROSS-REFERENCE TO RELATED APPLICATIONS

None.

### FIELD OF THE DISCLOSURE

The present invention relates to cooling electronics, and more specifically, to a method and apparatus for active cooling of electronics.

### BACKGROUND

Many electronic devices have growing heat dissipation challenges, due to the advancing power and performance of the electronic components within.

Passive cooling techniques including radiative cooling and convective cooling have been deployed as a solution to help dissipate the heat being generated. In radiative cooling, individual electronic components such as a CPU or GPU may utilize a heat sink with fins to help radiate heat away from such a point source. In convective cooling, convection is utilized, coupled with grills or exhaust ports on the case/back panel of the device to allow heated air to escape from the device enclosure.

Further, active cooling techniques may also be used when passive radiative and convective cooling is insufficient. For example, an axial fan may be used to actively move air across a heat sink, or more generally within the device housing and across the electronic components/PCBs within, thus increasing cooling air flow. At the same time, modern electronic device design choices often favor very flat or low-profile enclosures (e.g., a TV for wall mounting), and in some applications, the devices may have no space at all between one side of the internal PCB and a surface of the device (such as a display screen surface on the front of a TV). This significantly limits the gap or spacing between the electronic components and PCBs within the device and the exterior device casing, often to a space of less than 5 mm. It may also restrict cooling air movement to only one side of an internal PCB or prohibit the ability to move air through the PCB itself. This size constraint can prohibit the application of an axial fan in such a device, because such a fan may lack the clearance necessary to fit within the enclosure.

In addition, high fidelity audio and video recording can be degraded by the vibration and sound of an axial fan mounted within the electronic device itself to supply active cooling.

Ionic air movers have previously been described. For example, U.S. Pat. No. 8,824,142 to Panasonic Precision Devices Co., Ltd., entitled, “Electrohydrodynamic fluid mover for thin, low-profile or high aspect ratio electronic devices” discloses an ionic air mover built into the interior cavity of an electronic device. To operate, the air mover of the '142 patent requires room inside the device, and hence would be unable to operate in areas where the gap between the emitter and collector are so small as to allow arcing, and thus would prevent ionizing/moving air to cool components. Further, the design of the ionic air mover of the '142 patent puts the collector electrodes parallel to the airflow, built flat onto interior surfaces, and giving rise to additional problems. The airflow boundary layer along the surface will slow airflow velocity and hence limit cooling performance.

While there have been advanced in cooling technology, there remains a continued need for improved cooling systems and method for electronic devices. All patents, patent applications, and non-patent literature cited are hereby incorporated by reference in their entireties, for all purposes.

### BRIEF SUMMARY OF THE PRESENT INVENTION

The present invention provides an electronic device with an active cooling mechanism. The present invention attaches an ionic wind generator as an assembly to/formed integral with, an opening on outside of electronic device enclosure. The invention provides a sleek flat form factor FR4 mounted ionic wind generator assembly. The electronic device includes a housing, an ionic wind generator assembly for generating an airstream flowing in and out of the housing to cool internal components of the device, and a cover assembly configured to align over the ionic wind generator assembly for protecting against accidental contact of the ionic wind generator providing a uniform appearance.

The electronic device of the present invention has a more effective cooling solution than merely passive convective flow, analogous to using an axial fan, but which does not vibrate, operates silently, and most critically will fit in nearly flat enclosures with minimal air gap space between the active electronics to be cooled, and the device case itself. Further, the collector arrays of the ionic wind generator assembly are directly in the airflow, thereby moving air past/through gaps in the collector electrode array. Advantageously, the present invention requires no additional dialectic lining of interior components of the device since all ionization occurs at exterior air vents and is in the ionic wind generator assembly, whose structure offers sufficient electric charge isolation.

Embodiments of an ionic wind generator can be constructed to perform particular operations or actions by virtue of having software, firmware, hardware, or a combination of them installed, that in operation causes or cause the ionic wind generator to perform actions. One or more computer programs can be configured to perform particular operations or actions by virtue of including instructions that, when executed by data processing apparatus, cause the ionic wind generator to perform the actions.

One general aspect includes an electronic device having a catalyst integrated to or accommodated on the cover assembly of the device for ionization of the airstream to decompose ozone. The ionized airflow cools internal electronic components mounted on or near the PCB. Other embodiments of this aspect include corresponding computer systems, apparatus, and computer programs recorded on one or more computer storage devices.

Another general aspect includes an electronic device with an ionic wind generator assembly having a bracket to mount at least one ion wind generator, the ionic wind generator comprises an emitter and a collector, oriented to control the direction of the airstream for cooling of internal components.

Another general aspect includes an electronic device with a cover assembly having a plurality of bars/grills configured to align with collector pins of the ionic wind generator when the collector is oriented to be facing an anterior of the cover assembly.

Another general aspect includes an electronic device with a cover assembly configured to align with an emitter of an ionic wind generator when the emitter is oriented to be facing an anterior of the cover assembly.

Another general aspect includes an electronic device with a cover assembly having a back surface with a mesh configuration having the plurality of bars and airstream outlets, the cover assembly configured to removably accommodate the catalyst.

Another general aspect includes an electronic device with a cover assembly in an open bracket configuration fixed to an exterior casing surface of the device. The cover assembly is configured to extend outwardly from the exterior casing surface for holding a catalyst.

Another general aspect includes an electronic device configured within one or more of a television, a display panel, a laptop, a computer, a mobile, and a handheld digital device.

Another general aspect includes an electronic device having an ionic wind generator assembly, a catalyst, and a cover assembly manufactured by additive manufacturing process or injection molding manufacturing or hybrid manufacturing process.

Another general aspect includes an electronic device having a heat sink accommodated below a cover assembly enabling cooling of high-power heat sources.

Another general aspect includes a method of generating an ionized airstream for an electronic device. The method includes mounting at least one ionic wind generator on a bracket, wherein the ionic wind generator comprises an emitter and a collector oriented to enable cooling of internal components of the electronic device, and, integrating or accommodating a catalyst for decomposing ozone on a cover assembly, the assembly configured to align over the ionic wind generator assembly to act as a protective barrier against accidental contact of the ionic wind generator, wherein the catalyst enables reduction of ozone generated by ionization of air generated by the ionic wind generator assembly, the airstream flowing in and out of the electronic device to cool the internal components of the device. The method further includes the steps of analyzing by computer graphical means, an internal and external structure of the electronic device with the internal components; and, determining an appropriate configuration of ionic wind generator, the catalyst and the cover assembly for manufacturing based on the analysis to enable generation of ionized airstream for cooling of internal components of the electronic device.

Elements disclosed as being part of a particular general aspect or embodiment should not be taken to be limited to that particular general aspect or embodiment. Rather, any elements described for use in one particular embodiment may be incorporated into any other embodiment. In addition, the general aspects described may provide for working embodiments without every disclosed limitation.

### BRIEF DESCRIPTION OF THE DRAWINGS

FIG. 1 is an exploded view of an electronic device with an ionic wind generator assembly;

FIG. 2 is a side view of the electronic device of FIG. 1;

FIG. 3 is a side view of an electronic device with airstream actively pulled/intake inside the electronic device;

FIG. 4 is a side view of an electronic device with airstream pushed/exhaust outside the electronic device;

FIG. 5 is an exploded view of an electronic device accommodating a cover assembly with bars/grills;

FIG. 6 is a side view of the electronic device accommodating the cover assembly with bars/grills of FIG. 5;

FIG. 7 is an exploded view of an electronic device accommodating a cover assembly with rigid back pane surface and slotted sides;

FIG. 8 is a side view of the electronic device accommodating the cover assembly of FIG. 7;

FIG. 9 is an exploded view of a cover assembly with mesh configuration to be accommodated on an electronic device case;

FIG. 10 is an exploded view of a cover assembly with open bracket configuration to be accommodated on an electronic device case;

FIG. 11 is a side view of an electronic device with integrated catalyst configuration;

FIG. 12 is a side view of an electronic device with a heat sink below a cover assembly.

### DESCRIPTION OF THE INVENTION

The invention now will be described more fully hereinafter with reference to the accompanying drawings, in which embodiments of the invention are shown. This invention may however be embodied in many different forms and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. As used herein, the term “and/or” includes any and all combinations of one or more of the associated listed items.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section.

It will be understood that the elements, components, regions, layers and sections depicted in the figures are not necessarily drawn to scale.

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom,” “upper” or “top,” “left” or “right,” “above” or “below,” “front” or “rear,” may be used herein to describe one element's relationship to another element as illustrated in the Figures. It will be understood that relative terms are intended to encompass different orientations of the device in addition to the orientation depicted in the Figures.

Unless otherwise defined, all terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. The invention illustratively disclosed herein suitably may be practised in the absence of any elements that are not specifically disclosed herein. The electronic device with ionic wind generator assembly in the embodiments described below is built with PCB that houses the internal components/circuit elements that require cooling. This creates an ionic wind generator assembly directly where it is needed, in order to dissipate heat from heat generating components such as processors, memory, radios, etc., which require cooling. Moreover, the location of the ionic wind generators can be factored into the design requirement, knowing the tight gap between the PCB and the casing of the electronic device.

While the present disclosure explains the invention with a television and its structure in an example embodiment, it shall be apparent to a person skilled in the art that the invention can be implemented in any electronic device with space constraints such as laptop, computer, mobile, or a handheld digital device and that require efficient cooling.

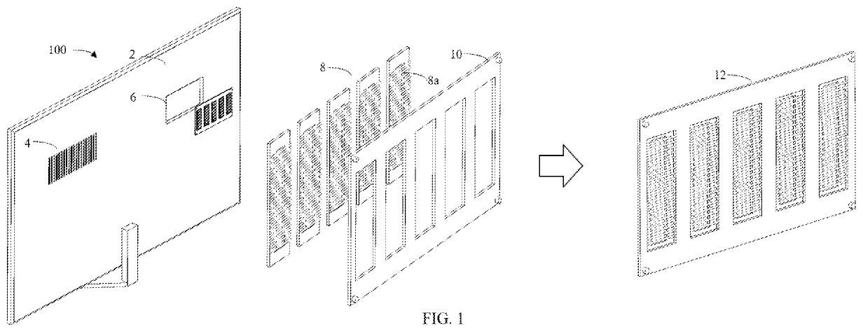

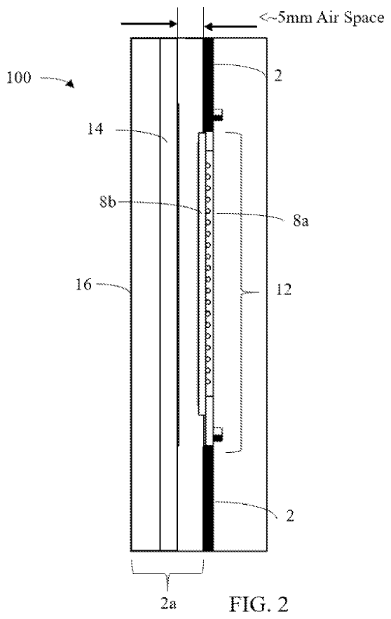

Turning to FIGS. 1 and 2, an embodiment of an electronic device 100 is shown in an exploded view (FIG. 1) and side (FIG. 2). The electronic device 100 includes an external casing/back panel 2 accommodating inlet/outlet port 4 for flow of air stream and an open port 6 for accommodating an ionic wind generator assembly 12. The wind generator assembly 12 includes a plurality of ionic wind generator 8 mounted on a bracket 10 to form a cover assembly to be fixed at the open port 6 of the electronic device. The ionic wind generator assembly 12 is configured such that the collector 8a of the ionic wind generator 8 is on the outside of the electronic device housing 2a while the emitter 8b of the ionic wind generator 8 is facing inside the electronic device housing 2a. The electronic device 100 further includes a PCB 14 embedded with one or more electronic components that generate heat and require cooling. The PCB 14 is secured between a display screen 16 and the ionic wind generator assembly 12.

It shall be apparent to a person skilled in the art that while the assembly 12 is shown to be directly fixed on the electronic device casing 2, in other embodiments as will be detailed later in the disclosure, the arrangement and positioning of the assembly shall be possible on additional objects that may be removably fixed to the electronic device casing 2.

In an alternate embodiment, the ionic wind generator assembly 12 may be configured such that the collector 8a of the ionic wind generator 8 is on the inside of the electronic device housing while the emitter 8b of the ionic wind generator 8 is facing outside the electronic device housing. Since, such a configuration presents challenges with respect to inadvertent events of shock, in such a configuration the wiring on the emitter shall be coated with a catalyst or insulating material.

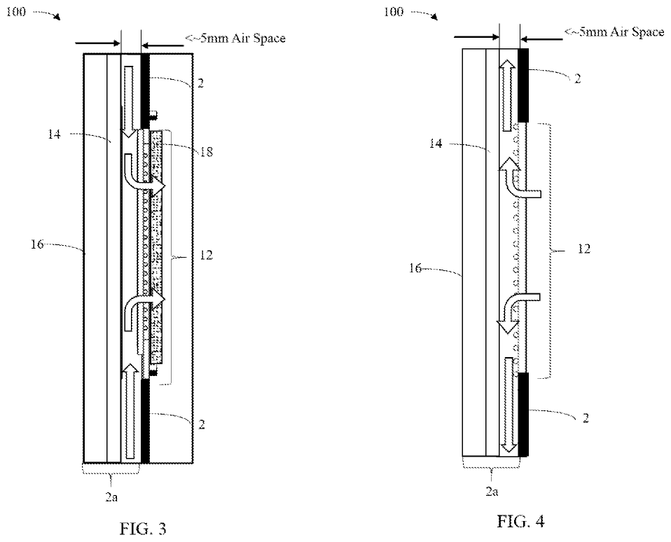

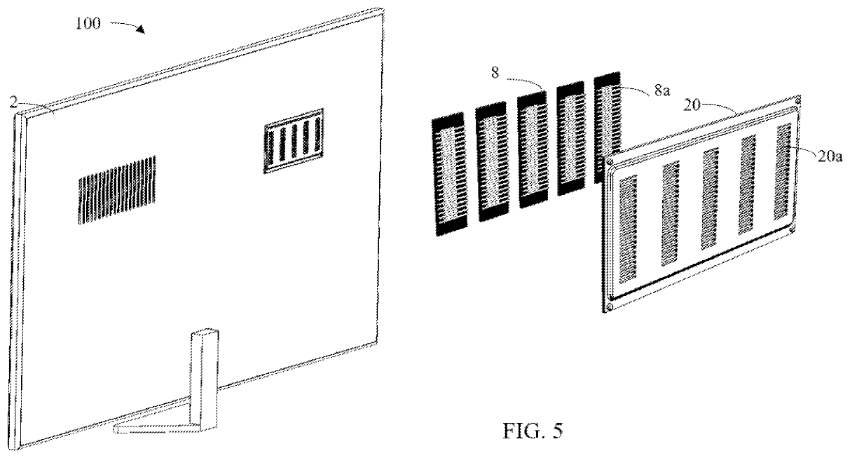

Referring to FIG. 3 and FIG. 4 an embodiment of the electronic device 100 is shown with airstream actively pulled/intake inside the electronic device (FIG. 3) and alternatively, airstream pushed/exhaust outside the electronic device (FIG. 4). The airflow is pulled into the electronic device (FIG. 4) through the ionic wind generator assembly 12, then pushed against the PCB 14 containing hot electronic components as a downdraft and turning at out about 90 degrees as an outflow from such downdraft. Alternatively, the airstream is pulled along the PCB 14 containing hot electronic components, and then turned at or about 90 degrees to exhausted as an updraft out of the housing through the ionic wind generator assembly 12. The assembly 12 is connected by an electrical connector to a power supply on the internal PCB but otherwise, the assembly is electrically isolated from the internal components within the electronic device. Further, the assembly 12 is protected from damage/contact from the outside by a non-conductive cover assembly, slotted sufficiently to allow air to pass through. If airstream is being exhausted instead of being pulled in through the assembly 12, a layer of ozone catalyst 18 is built into the cover assembly for ionization of the airstream.

The gap between the Printed Circuit Board (PCB) 14 embedded with the internal components and the ionic wind generator assembly 12 is less than or about 5 mm.

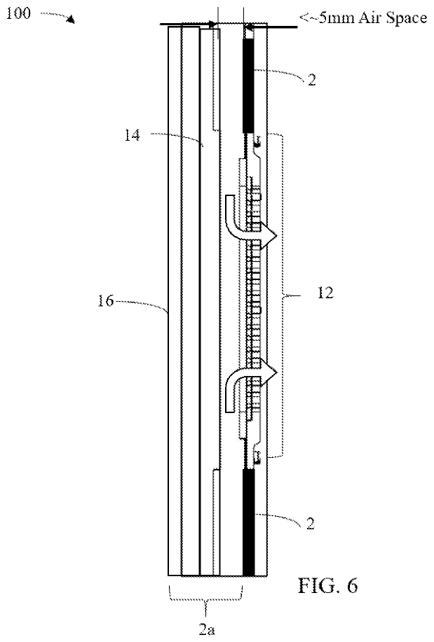

Referring to FIG. 5 and FIG. 6, an embodiment of the electronic device 100 is shown in exploded view (FIG. 5) and side view (FIG. 6). The electronic device 100 includes a removably attached cover assembly 20 on the case/back panel 2. The cover assembly comprises a plurality of bars/grills 20a configured to align with collector pins of the ionic wind generator assembly 12 when the collector 8a is oriented to be facing an anterior of the cover assembly 20. The bars/grills may add 1.5 mm to thickness but allows for catalyst coating and it does not reduce the 5 mm between the PCB 14 and the ionic wind generator assembly 12. The airstream is exhausted through the bars/grill of the cover assembly (FIG. 6) thereby cooling the internal components embedded on the PCB 14 of the electronic device.

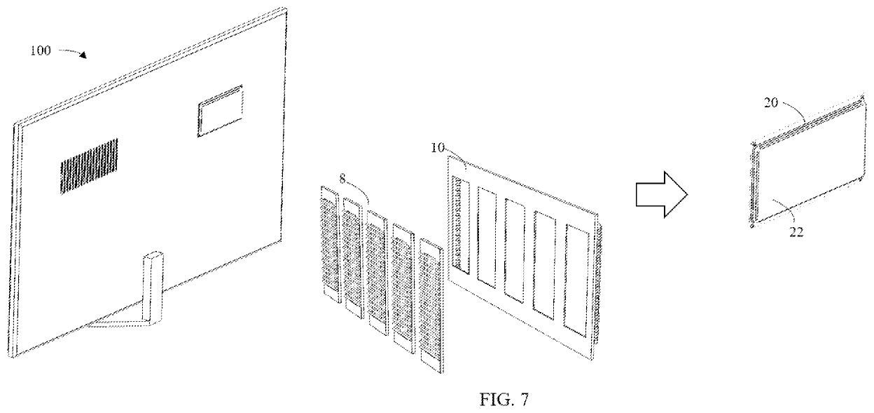

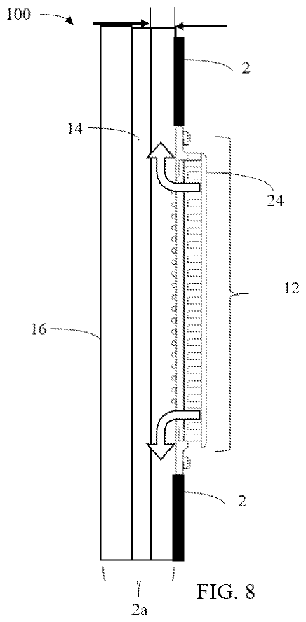

Referring to FIG. 7 and FIG. 8, an embodiment of the electronic device 100 is shown in exploded view (FIG. 7) and side view (FIG. 8). The electronic device 100 includes a removably attached cover assembly 20 with a rigid back pane surface 22 and slotted sides 24 configured to pull or intake the airstream. Further, the cover assembly 20 is configured to align with the emitter 8b of the ionic wind generator assembly 12 when the emitter 8b is oriented to be facing an anterior of the cover assembly 20 thereby eliminating any accidental touch to the emitter side of the assembly. The airstream is pulled inside the electronic device through the slotted sides 24 of the cover assembly 20 (FIG. 8) thereby cooling the internal components embedded on the PCB 14 of the electronic device 100.

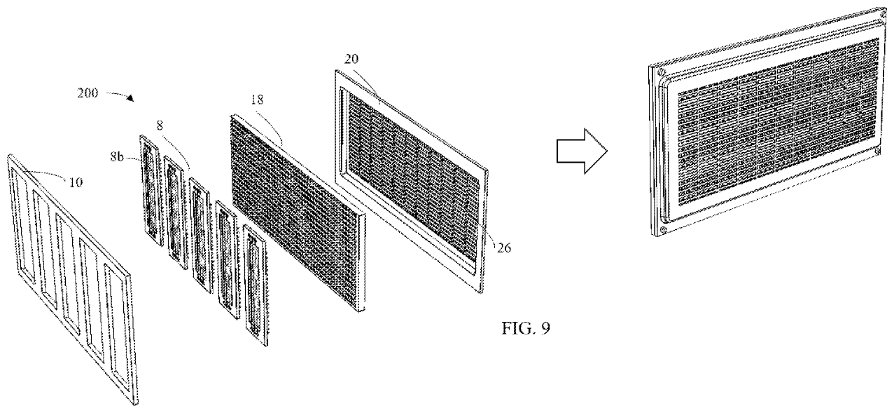

Referring to FIG. 9, an exploded view 200 of a cover assembly 20 with mesh configuration is shown in accordance with an embodiment of the invention. The cover assembly 20 includes a back surface with a mesh configuration 26 having a plurality of bars and airstream outlets. The cover assembly 20 is configured to removably accommodate the catalyst 18 placed between the ionic wind generator assembly 12 and the cover assembly 20.

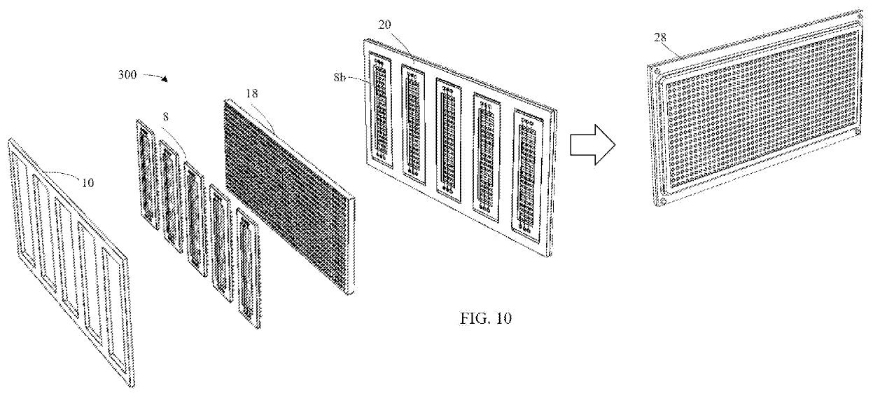

Referring to FIG. 10, an exploded view 300 of a cover assembly with an open bracket configuration is shown in accordance with an embodiment of the invention. The cover assembly 20 includes an open back surface and a frame structure 28 configured to hold the catalyst 18. The cover assembly 20 in the open bracket configuration is fixed to an exterior casing 2 of the device. The cover assembly 20 in an open bracket configuration extends outwardly from the exterior casing 2 for holding the catalyst 18.

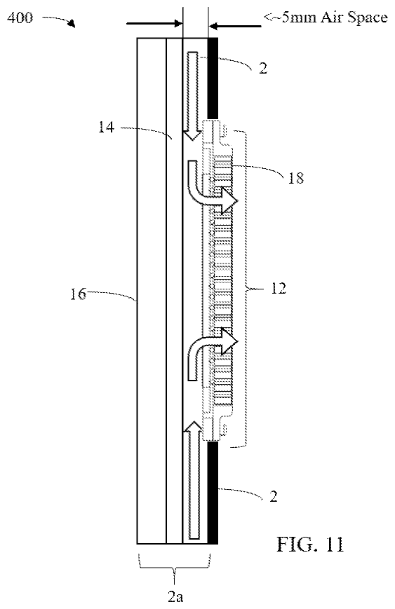

Referring to FIG. 11, a side view of an electronic device with integrated catalyst configuration 400 is shown in accordance with an embodiment of the invention. While in a preferred embodiment, the catalyst 18 is an ozone catalyst honeycomb foam structure of between 3 mm and 5 mm in thickness, it shall be apparent to a person skilled in the art that the thickness of the catalyst may vary anything between 1 mm and 6 mm. The airstream is exhausted through the catalyst accommodated on the cover assembly thereby cooling the internal components embedded on the PCB 14 of the electronic device.

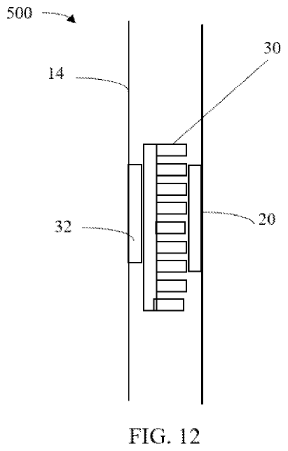

Referring to FIG. 12, a side view 500 of an electronic device with ionic wind generator assembly 12 over a heat sink 30 is shown in accordance with an embodiment of the invention. The heat sink 30, is accommodated below the cover assembly 20 enabling cooling of High-Power heat sources 32.

In an embodiment, the present invention provides a method of generating an ionized airstream for an electronic device, where the components/elements enabling cooling inside the electronic device are manufactured by additive manufacturing, injection molding, stamping process or hybrid manufacturing process. The method includes the step of issuing a printing command to a 3D printer to print manufacture the ionic wind generator assembly, the catalyst, and the cover assembly or ionized cover assembly based on the required configuration as determined after analysis.

Exemplary embodiments of the present invention may be a system, a method, and/or a computer program product for the manufacturing of the electronic devices or related components through identification of required dimensions by data analysis. The computer program product may include a computer readable storage medium (or media) having computer readable program instructions thereon for causing a processor to carry out aspects of the present invention including but not limited to processing prediction algorithm, determining configuration related data for components of the electronic device etc. The media has embodied therein, for instance, computer readable program code (instructions) to provide and facilitate the capabilities of the present disclosure. The article of manufacture (computer program product) can be included as a part of a computer system/computing device or as a separate product.

In a preferred embodiment, the present invention uses SLA (stereolithography) to produce initial samples of cover assembly with plastic components or a more cost-effective way by injection molding the cover assembly if made of plastic material or if it is metal, a stamping method. As for the catalyst coating the plastic over the ionic wind generator, it is through spray coating/dry process. The emitter wire of the ionic wind generator assembly is coated with insulating material. The ion wind generator substrate is preferably a PCB (FR4), with appropriate circuitry, and is created in a standard PCB Fabrication.

Variations of the type, form, size, and material of any emitter, collector, cover assembly, ionic wind generator assembly, PCB may be of any of those described previously and used in any of the method described.

### REFERENCE NUMBERS

The following reference numbers are used throughout FIGS. 1-12:
100 electronic device
200 mesh configuration cover assembly
300 Open bracket configuration cover assembly
400 Integrated catalyst configuration electronic device
500 Heat sink implemented electronic device
2 case/back panel of the electronic device
2a housing
4 airstream Inlet/outlet port of the electronic device
6 open port
8 ionic wind generator
8a is collector side of the generator with collector pins
8b is emitter side of the generator
10 bracket to mount the ionic wind generator
12 ionic wind generator assembly
14 PCB
16 Display screen of the device
18 Catalyst
20 Cover assembly
20a bars/grill of Cover assembly
22 rigid back pane surface cover assembly
24 slotted sides of the cover assembly
26 mesh cover assembly
28 frame structure of the cover assembly
30 Heat Sink
32 High Power chip/heat sources

While the invention has been described in terms of exemplary embodiments, it is to be understood that the words that have been used are words of description and not of limitation. As is understood by persons of ordinary skill in the art, a variety of modifications can be made without departing from the scope of the invention defined by the following claims, which should be given their fullest, fair scope.

What is claimed is:

1. An electronic device comprising:
a housing;
an ionic wind generator assembly for generating an airstream flowing in and out of the housing to cool internal components of the electronic device; and,
a cover assembly configured to align over the ionic wind generator assembly for protecting against inadvertent contact of the ionic wind generator assembly providing a uniform appearance.

2. The electronic device of claim 1, further comprising:
a catalyst integrated to, or accommodated on the cover assembly for ionization of the airstream to decompose ozone.

3. The electronic device of claim 2, wherein the ionic wind generator assembly comprising a bracket to mount at least one ion wind generator, the ionic wind generator assembly comprising an emitter and a collector, oriented to control direction of the airstream for cooling of internal components.

4. The electronic device of claim 3, wherein the cover assembly comprising a plurality of bars/grills configured to align with collector pins of the ionic wind generator assembly when the collector is oriented to be facing an anterior of the cover assembly.

5. The electronic device of claim 3, wherein the cover assembly is configured to align with the emitter of the ionic wind generator assembly when the emitter is oriented to be facing an anterior of the cover assembly; and wherein the cover assembly includes a rigid back pane surface and slotted sides configured to pull or intake the airstream; and wherein the electronic device is configured to permit the airstream being pulled into the housing of the electronic device through the ionic wind generator assembly, then pushed against the internal components as a downdraft, and turned at or about 90 degrees as an outflow from the downdraft.

6. The electronic device of claim 4, wherein the cover assembly comprises a back surface with a mesh configuration having the plurality of bars/grills and airstream outlets, the cover assembly configured to removably accommodate the catalyst; and wherein the cover assembly is an open bracket configuration fixed to an exterior casing surface of the electronic device, the cover assembly is configured to extend outwardly from the exterior casing surface for holding the catalyst; and wherein the catalyst is a catalyst honeycomb foam structure of between 1 mm and 6 mm in thickness; and wherein the electronic device is configured to permit the airstream being pulled along the internal components of the electronic device, and then turned at or about 90 degrees to be exhausted as an updraft out of the housing through the ionic wind generator assembly.

7. The electronic device of claim 1, wherein the ionic wind generator assembly is electrically isolated from the internal components of the electronic device.

8. The electronic device of claim 7, wherein a gap between a Printed Circuit Board (PCB) embedded with the internal components and the ionic wind generator assembly is less than or about 5 mm.

9. The electronic device of claim 1, configured within one or more of a television, a display panel, a laptop, a computer, a mobile, and a handheld digital device.

10. The electronic device of claim 2, wherein the ionic wind generator assembly, the catalyst, and the cover assembly is manufactured by additive manufacturing process or injection molding manufacturing or hybrid manufacturing process.

11. The electronic device of claim 2 further comprising a heat sink accommodated below the cover assembly enabling cooling of High-Power heat sources.

12. A method of generating an airstream for an electronic device, the method comprising:
mounting an ionic wind generator assembly on a bracket, wherein the ionic wind generator assembly comprises an emitter and a collector oriented to enable cooling of internal components of the electronic device; and,
integrating or accommodating a catalyst for decomposing ozone on a cover assembly, the cover assembly configured to align over the ionic wind generator assembly to act as a protective barrier against accidental contact of the ionic wind generator assembly, and;
wherein the catalyst enables reduction of ozone generated by ionization of air generated by the ionic wind generator assembly, the airstream flowing in and out of the electronic device to cool the internal components of the electronic device.

13. The method of claim 12, further comprising orienting the collector of the ionic wind generator assembly to be facing an anterior of the cover assembly and a plurality of bars/grills are provided on the cover assembly configured to align with collector pins.

14. The method of claim 12, further comprising orienting the emitter of the ionic wind generator assembly to be facing an anterior of the cover assembly, wherein the cover assembly is configured to align with the emitter; and further comprising providing a rigid back pane surface on the cover assembly and providing slotted sides on the cover assembly configured to permitting pulling or intaking of the airstream; and wherein the airstream is pulled into the electronic device through the ionic wind generator assembly then pushed against the internal components as a downdraft and turned at or about 90 degrees as an outflow from such downdraft.

15. The method of claim 13, further comprising providing a mesh configuration with the plurality of bars/grills and airstream outlets at a back surface of the cover assembly wherein the cover assembly is configured to removably accommodate the catalyst; and further comprising structuring the cover assembly as an open bracket configuration to be fixed to an exterior casing surface of the electronic device, the cover assembly is configured to extend outwardly from the exterior casing surface for holding the catalyst; and wherein the catalyst is structured as a catalyst honeycomb foam of between 1 mm and 6 mm in thickness; and further comprising integrating the catalyst on the cover assembly or coating the cover assembly with the catalyst.

16. The method of claim 12, wherein the airstream is pulled along the internal components of the electronic device and then turned at or about 90 degrees to be exhausted as an updraft out of a housing of the electronic device through the ionic wind generator assembly.

17. The method of claim 12, wherein the ionic wind generator assembly is electrically isolated from the internal components of the electronic device.

18. The method of claim 17, wherein a gap between a PCB embedded with the internal components and the ionic wind generator assembly is less than or equal to 5 mm.

19. The method of claim 12, further comprising the steps of:
analyzing by computer graphical means, an internal and external structure of the electronic device with the internal components; and,
determining an appropriate configuration of ionic wind generator assembly, the catalyst and the cover assembly for manufacturing based on the analysis to enable generation of the airstream for the electronic device.

20. The method of claim 19, further comprising issuing a printing command to a 3D printer to print manufacture the ionic wind generator assembly, the catalyst, and the cover assembly or ionized cover assembly based on the determined configuration; and further comprising manufacturing of the cover assembly by injection molding, stamping process, or hybrid manufacturing process.
